(19) United States
(12) Patent Application Publication
(10) Pub. No.: US 2018/0091174 A1
(43) Pub. Date: Mar. 29, 2018

(54) PROGRESSIVE POLAR CHANNEL CODING IN FLASH MEMORY AND COMMUNICATIONS

(71) Applicant: SAMSUNG ELECTRONICS CO., LTD., SUWON-SI (KR)

(72) Inventors: ERAN HOF, RAMATGAN (IL); MOSHE TWITIO, RAMATGAN (IL); GUY INBAR, RAMATGAN (IL); JUN JIN KONG, YONG IN-SI (KR); YARON SHANY, RAMATGAN (IL)

(21) Appl. No.: 15/277,708

(22) Filed: Sep. 27, 2016

(51) Int. Cl. H03M 13/00; G06F 11/10; G11C 29/52; H04L 1/00; H03M 13/13

(52) U.S. Cl. CPC H03M 13/6337; G06F 11/1068; H03M 13/13; H04L 1/0041; H04L 1/0058; G11C 29/52

(57) ABSTRACT

A method for storing data in a solid state device includes applying polar coding to generate channels including perfect channels, useless channels, and channels that are neither perfect nor useless. Some data is encoded using the perfect channels. A predetermined value is encoded using the useless channels. The other channels are divided into groups, depending upon a quality of each channel. Other data is encoded using the channels that are neither perfect nor useless using a different coding technique. This coding technique is applied to the same quality channels using several polar codewords, in parallel. Decoding is carried in a progressive parallel manner where the other coding technique assists the decoding of some polar codewords based on correct results from other polar codewords that were successfully decoded. The encoded data to be stored is written into the solid state device or transmitted.

### TECHNICAL FIELD

The present disclosure relates to error correcting coding in flash memory and communications, and more specifically, to methods and systems for using polar codes in a progressive manner for error correction coding in flash memory and communications.

### DISCUSSION OF THE RELATED ART

According to the theory of noisy-channel coding, there are ways in which digital information may be transmitted reliably through a noisy channel, without errors, by using certain coding approaches. Channels may have a particular bandwidth and certain coding techniques have greater overhead than others. The noisier the channel, the greater the overhead of the coding technique needed to ensure reliable transition, and accordingly, noisy channels often have very slow data transmission rates.

One approach for coding that is theoretically able to provide optimal data transmission rates for noisy channels (referred to as “achieving capacity”) involves the use of polar codes. In polar coding, ideally (“asymptotically” in mathematical terms), two types of channels are produced, the perfect channel, in which successful reliable transmission of transmitting information is guaranteed, and the useless channel, in which it is theoretically impossible to transmit information.

As flash memory devices increase in capacity and decrease in size, the opportunity for correctly programmed memory cells to spontaneously jump to an incorrect state increases. These spontaneous jumps can corrupt the data that is stored in the flash memory devices.

One approach for increasing reliability in these highly-integrated flash memory devices is to store data therein using error correction codes (“channel coding”). In this case, the storage of data within the flash memory, and the retrieval of data therefrom, is treated like a noisy channel, and by applying channel coding to the data as it is stored, and channel decoding to the data as it is retrieved, the integrity of the data can be preserved, with costs accruing to the total capacity of the memory device and the speed at which data can be stored and retrieved.

In theory, polar coding can be a preferred candidate for error correcting codes for storage of data within flash memory. However, one practical problem with polar coding is that the polarizing of channels into perfect channels and useless channels is only fully realized at the theoretical condition in which blocks of the flash memory are infinitely long. As flash memory devices have blocks of fixed and finite lengths, in practice, there are a large number of channels that are neither perfect channels nor useless channels, frustrating the application of polar channel coding in flash memory.

### SUMMARY

A method for storing data to be stored in a solid state device includes applying polar coding to generate a plurality of channels including a plurality of perfect channels, a plurality of useless channels, and a plurality of channels that are neither perfect nor useless. A first section of the data to be stored is encoded using the perfect channels. A predetermined value is encoded using the useless channels. The plurality of channels that are neither perfect nor useless are divided into a plurality of groups, depending upon a quality of each channel of the plurality of channels that are neither perfect nor useless. A second section of the data to be stored is encoded using the channels that are neither perfect nor useless using a coding technique that is different from the applied polar coding. The encoded data to be stored is written into the solid state device.

In encoding the second section of the data to be stored using the channels that are neither perfect nor useless using a coding technique that is different from the applied polar coding, a different coding technique may be used for each of the plurality of groups. The different coding technique may be applied to corresponding groups of channel quality from several different polar codewords. The different coding technique may be selected in accordance with the channel quality of the corresponding group.

The different coding techniques may include encoding using redundancy and greater redundancy may be used for groups with lesser channel quality.

The method may further include reading the encoded data from the flash memory. The read data may be decoded from the perfect channels using polar decoding. The read data may be decoded from the plurality of channels that are neither perfect nor useless using the polar decoding and a second decoding technique that is different from the polar decoding.

In decoding the read data from the plurality of channels that are neither perfect nor useless using the polar decoding, erroneous decoding may be cured by using, as a predetermined value, redundant data that was successfully decoded from the read data from the corresponding same plurality of channels that are neither perfect nor useless of the different polar codewords. The decoded read data may be transmitted to a host device.

The data to be stored may be received from a host device.

A method for transmitting data includes applying polar coding to generate a plurality of channels including a plurality of perfect channels, a plurality of useless channels, and a plurality of channels that are neither perfect nor useless. A first section of the data to be transmitted is encoded on the perfect channels. A predetermined value is encoded on the useless channels. The plurality of channels that are neither perfect nor useless are divided into a plurality of groups depending upon a quality of each channel of the plurality of channels that are neither perfect nor useless. A second section of the data to be transmitted on the channels that are neither perfect nor useless is encoded using a coding technique that is different from the applied polar coding. The encoded data is sent to a recipient.

The encoded data may be sent to the recipient wirelessly.

In encoding the second section of the data to be transmitted using the channels that are neither perfect nor useless using a coding technique that is different from the applied polar coding, a different coding technique may be used for each of the plurality of groups. The different coding technique may be applied to corresponding groups of channel quality from several different polar codewords. The different coding technique may be selected in accordance with the channel quality of the corresponding group. Decoding may be carried out in a progressive manner from best to worst channels generated from the polarization effect where several polar codewords are decoded in parallel. The correct information of a given plurality of channels from some codewords assist the decoding of the corresponding same quality of channels of other codewords as if these are predetermined and fixed bits.

The different coding techniques may include encoding using redundancy and greater redundancy may be used for groups with lesser channel quality.

The encoded data may be received at the recipient. The received data may be decoded from the perfect channels using polar decoding. The received data may be decoded from the plurality of channels that are neither perfect nor useless using the polar decoding and a second decoding technique that is different from the polar decoding.

In decoding the received data from the plurality of channels that are neither perfect nor useless using the polar decoding, erroneous decoding may be cured by using, as a predetermined value, redundant data that was successfully decoded from the received data from the corresponding same plurality of channels that are neither perfect nor useless from the different polar codewords. Decoding may be carried out in a progressive manner from best to worst channels generated from the polarization effect where several polar codewords are decoded in parallel. The correct information of a given plurality of channels from some codewords may assist the decoding of the corresponding same quality of channels of other codewords as if these are predetermined and fixed bits.

The decoded received data may be transmitted to a host device. The data to be transmitted may be received from a host device.

A method for encoding data includes applying polar coding to generate a plurality of channels including a plurality of perfect channels, a plurality of useless channels, and a plurality of channels that are neither perfect nor useless. A first section of the data to be stored is encoded using the perfect channels. A predetermined value is encoded using the useless channels. The plurality of channels that are neither perfect nor useless are divided into a plurality of groups that includes at least a first group of channels having a relatively high channel quality and a second group of channels having a relatively low channel quality. A second section of the data to be stored is encoded using the channels of the first group of channels having the relatively high channel quality using a first level of redundancy. A third section of the data to be stored is encoded using the channels of the second group of channels having the relatively low channel quality using a second level of redundancy that is greater than the first level of redundancy.

The method may further include writing the encoded data to be stored into a solid state device. The encoded data may be transmitted to a recipient. The encoded data may be transmitted to the recipient wirelessly.

The encoded data may be decoded using polar decoding, and, in decoding the channels that are neither perfect nor useless, erroneous decoding may be cured by using, as a predetermined value, redundant data that was successfully decoded from the other polar codewords that are decoding in parallel via the progressive manner suggested.

### BRIEF DESCRIPTION OF THE DRAWINGS

A more complete appreciation of the present disclosure and many of the attendant aspects thereof will be readily obtained as the same becomes better understood by reference to the following detailed description when considered in connection with the accompanying drawings, wherein:

FIG. 1 is a flow chart illustrating an approach for performing progressive polar channel coding according to exemplary embodiments of the present invention;

FIG. 2 is a flow chart illustrating an approach for performing progressive polar channel decoding according to exemplary embodiments of the present invention;

FIG. 3 is a schematic diagram illustrating a system for performing progressive polar channel coding in flash memory in accordance with exemplary embodiments of the present invention; and

FIG. 4 is a schematic diagram illustrating a system for performing progressive polar channel coding for transmission in accordance with exemplary embodiments of the present invention.

### DETAILED DESCRIPTION OF THE DRAWINGS

In describing exemplary embodiments of the present disclosure illustrated in the drawings, specific terminology is employed for sake of clarity. However, the present disclosure is not intended to be limited to the specific terminology so selected, and it is to be understood that each specific element includes all technical equivalents which operate in a similar manner.

Exemplary embodiments of the present invention seek to use polar channel coding in storing and retrieving data from flash memory and overcome the problems associated with the occurrence of channels that are neither perfect nor useless. However, it is to be understood that while many of the exemplary embodiments discussed herein relate to the use of storing and retrieving data from flash memory devices, exemplary embodiments of the present invention may also be applied to the transmission of data through noisy channels, such as the wireless transmission of digital data, using polar channel coding while overcoming the problems associated with the occurrence of channels that are neither perfect nor useless.

In conventional polar coding, information is transmitted along the perfect channels and the useless channels are predetermined to carry fixed values that are known to the device decoding the information stored in the flash memory, or by the device decoding the received transmission. It is important that the fixed values of the useless channels be known at the decoding end as decoding polar codes may fail if the value of channels is not known. Accordingly, these useless channels may be configured to send only a predetermined value such as zero. It is understood that in decoding, it can be established, by the decoder, which channels are the useless channels and so the decoder can know to assign the decoded information for these channels as the predetermined value, for example, zero.

Exemplary embodiments of the present invention handle the problem associated with channels that are neither perfect nor useless by identifying a measure of goodness for each channel and then grouping the channels together according to their level of goodness. By “goodness,” it is meant that channels are grouped together according to their ability to transmit information without error. Those channels that are perfect may then be used to transmit/store actual data, those channels that are useless may then be used to transmit/store the predetermined values, and those channels that are neither perfect nor useless may be used to transmit/store some amount of data that is dependent upon their degree of goodness, according to parallel encoding and decoding using additional polar code words.

For example, while the perfect channels may transmit/store actual data, without additional polar encoding, the group of channels that are nearly perfect may be used to carry data with the use of another layer of coding, for example, by using some small amount of redundancy. For example, each bit of data may be transmitted twice. This may be referred to herein as transmitting a half of a bit per channel, as it would take two channels to transmit each bit due to the redundancy. The group of channels that are moderately good may see additional redundancy such as each bit of data being transmitted on those channels three times, which may be referred to herein as transmitting ⅓ of a bit on each of these channels. The group of channels that are moderately bad may see even a higher degree of redundancy, such as each bit of data being transmitted on those channels ten times, which may be referred to herein as transmitting 1/10 of a bit on each of these channels. The group of channels that are nearly useless may see a relatively high degree of redundancy such as each bit of data being transmitted on those channels one thousand times, which may be referred to herein as transmitting 1/1000 of a bit on each of these channels.

The exact number of repetitions may be selected, based on the channel quality, so as to nearly assure that at least one of the channels carrying a given bit is successful and without error. In this way, the channel quality of each group may be determined so as to set the desired level of redundancy accordingly. In receiving/reading data, during decoding, exemplary embodiments of the present invention may use the correctly received bit to “interpret” all of the repetitive bits, as polar decoding requires that the value for each bit be decoded correctly in order to assure that any of the data is correctly read. For example, if a given bit that is repeated 10 times is received correctly as “1” on at least one channel, it may then be assumed that all of the other 9 channels are also “1” so that decoding may proceed.

This stands in contrast to traditional polar encoding in which each channel is either perfect or useless, and known to be of a particular prearranged value. Here, those channels that are in-between perfect and useless are used to carry data with one or more additional levels of coding, for example by redundancy, that is proportional to the quality of the channel. For the purposes of the original (outermost) iteration of polar coding, the in-between channels are regarded as perfect channels.

The above-described redundancy is offered merely as an example of a nested encoding technique. Other nested encoding techniques may be used, with each group of channels receiving an additional encoding technique with an overhead that is matched according to the quality of the channels in that group.

An exemplary approach of the above-described technique may be described in a more precise notation below. According to this notation, let Nᵣ>1 be the number of polar codewords, each codeword having a length N=2ⁿ, n≧1. The nested coding schemes corresponds to levels of quality of observations at the output of the polar decoders. These level of quality may be processed in a progressive manner, from worst to best. Decoding proceeds in a progressive iterative manner where several polar codewords are decoded, then nested (algebraic) codes are used for intermediate quality channels, and then again polar decoding is used, etc. At each stage, more progress is gained in the decoding as more bits are successfully decoded with the help of the nested codes.

The number of algebraic decoding stages may be denoted as S≧1 and let [symbol] ^{S}⊂[n], 0≦s≦S be S+1 disjoint index set (where for a positive integer J, let [J]={1, 2, . . . , J}). We denote by [symbol] , 0≦s≦S, the union of all index sets up to s. For example:

$${\overline{𝒜}}^{s} = {⋃}_{0 \leq {s}^{′} \leq s} {𝒜}^{{s}^{′}}$$

These codewords may be thought of as rows and for the introduced redundancy in intermediate quality, synthetic channels generated by the polar decoders may be thought of as coding in columns. As said, repetition for coding in columns is merely one option. Other options may be used. For example, on option is to use algebraic codes, in particular Maximum Distance Separable (“MDS”) codes, e.g. Reed-Solomon (RS) and extended RS codes.

The algebraic column codes for each algebraic decoding stage is of dimension kₛ, s∈[S]. The algebraic codes are defined over GF(q). For example, non-binary coding may be used for the nested codes. Note, for RS codes Nᵣ=q−1, the index sets may be chosen such that their cardinality are integral multiplications of q, for example:

| [symbol] ^{S}|=mₛ·log₂(q),s∈[S]

where mₛ, s∈[S] are positive integers equal to the number of algebraic codewords involved at the s stage. Note that the cardinality of [symbol] ⁰ is not directly conditioned by the alphabet cardinality q. A polar decoding operation for a given length N observation vector y and a set of information indices [symbol] ⊂[N] is denoted by D(y, u, [symbol] ) where u=(u₁, u₂ . . . , u_{N}) is a length N binary in-out vector. On indices i∈ [symbol] the value of uᵢ is predetermined and fixed. These values are therefore provided as an input to the decoding operation D. For indices i∈ [symbol] the value of uᵢ is an information bit set by the decoding operation D.

In the following description, an erasure symbol may be set for a binary variable or to a finite field variable. This erasure symbol is not part of the corresponding field and may therefore be considered as an unknown value of the considered variable.

In encoding, the encoding operation maps Nᵣ·N bits, u_{i,j}, i∈[Nᵣ], j∈[N] to a set of Nᵣ polar (row) codewords cᵢ, i∈[Nᵣ]. Some of the bits u_{i,j}, i∈[Nᵣ], j∈[N] are predetermined and fixed, some are plain information bits, and the remaining bits are set via algebraic constraints, for example, as detailed below. The bits u_{i,j},i∈[kₛ] and j∈ [symbol] ^{S}, s∈[S], as well as the bits in u_{i,j}, i∈[Nᵣ] and j∈ [symbol] ⁰, are all information bits. The total number of information bits K is therefore given by:

$$K = {N}_{r} \cdot \vert {𝒜}^{0} \vert + {\sum }_{s ∈ \vert S \vert} {k}_{s} \cdot \vert {𝒜}^{s} \vert$$

and the corresponding coding rate is given by:

$$R = \frac{K}{{N}_{r} \cdot N} = \frac{{𝒜}^{0}}{N} + {\sum }_{s ∈ \vert S \vert} \frac{{k}_{s}}{{N}_{r}} \cdot \frac{\vert {𝒜}^{s} \vert}{N} \qquad ( Eq . 1 )$$

For every decoding stage 1≦s≦S, the bits u_{i,j},i>kₛ, j∈ [symbol] ^{S} are derived via algebraic maximum distance separable (MDS) encoding of the information bits u_{i,j}, i∈[kₛ] and j∈ [symbol] ^{S}. For example, the codewords mₛ may be evaluated over GF(q) as:

Uₘ^{S}=(U_{m,1}^{S},U_{m,2}^{S}, . . . ,U_{m,N}_{ᵣ}^{S}),m∈[mₛ] (Eq. 2)

The symbols U_{m,i}^{S}, m∈[mₛ], i∈[kₛ] is the symbol in GF(q) corresponding to the binary q-tuple:

^{b}U_{m,i}^{S}=( [symbol] ^{S}(1+(m−1)·q), [symbol] ^{S}(2+(m−1)·q), . . . , [symbol] ^{S}(m·q)) (Eq. 3)

For i∈[kₛ], all the bits ^{b}U_{m,1}^{S} in Eq. 3 are information bits and therefore the corresponding symbol U_{m,i}^{S} is an information symbol. This operation fixes the value of the remaining Nᵣ−kₛ symbols U_{m,i}^{S}, kₛ<i≦Nᵣ in Uₘ^{S}, m∈[mₛ]. Consequently, the binary q-tuples ^{b}U_{m,i}^{S} for m∈[mₛ], kₛ+1≦i≦Nᵣ is set to the binary q-tuple corresponding to the GF(q) symbol U_{m,i}^{S}, m∈[mₛ], kₛ+1≦i≦Nᵣ. This concludes the setting of all the bits u_{i,j}, i∈[Nᵣ] and j∈ [symbol] ^{S}. The encoding process is repeated for all stages s∈[S] this concludes the setting of Nᵣ·N bits u_{i,j}, i∈[Nᵣ] and j∈[N].

Then, Nᵣ polar codewords cᵢ, i∈[Nᵣ] are evaluated according to:

cᵢ=uᵢ·G_{N}

Here, uᵢ=(u_{i,1}, u_{i,2}, . . . u_{i,N}) and G_{N} is the polar generator matrix of size N×N.

In performing decoding, it may be assumed that the Nᵣ polar codewords cᵢ, i∈[Nᵣ] are transmitted over a DMC, and let yᵢ, i∈[Nᵣ] be the corresponding channel observations. These observations may be a reading output from a solid state drive with NAND flash technology or a received sequence in a communication device. It may be assumed that for every polar codeword cᵢ, i∈[Nᵣ], the decoding success or failure is provided (e.g. with the help of cyclic redundancy check (CRC) codes). The first step of the decoding procedure is then to apply the following Nr polar decoding procedures for every polar codeword observation yᵢ, i∈[Nᵣ]:

D(yᵢ,uᵢ, [symbol] ^{S}) (Eq. 4)

where uᵢ=(u_{i,1}, u_{i,2}, . . . u_{i,N}) are in-out binary vectors for the decoding operations at hand, for which the bits u_{i,j} for indices j∉ [symbol] ^{S} must be provided as input to the decoding operations in Eq. 4. These input bits are the predetermined and fixed bits for the polar decoding operations. Note that [symbol] ^{S} is provided as an index set for the decoding operations in Eq. 4, the only variables in uᵢ which are considered as predetermined and fixed are the all-zero variables u_{i,j}, i∈[Nᵣ] and j∉ [symbol] ^{S}. In subsequent stages of the decoding procedure, these indices sets are altered and some of the input bits are information or manipulation of information bits. However, the input bits may be considered as predetermined and fixed by the polar decoding operations. Here the row indices of the successful polar decoding operations may be denoted as C_{S}⊂[Nᵣ]. After the decoding operations in Eq. 4 are conducted, the bits in are set by the polar decoding algorithm according to the correct information bit. Several options for the decoding operations in Eq. 4 (and eq. 5 in the following) may be considered. For example, successive cancellation decoding, list successive cancellation decoding, and belief-propagation decoding may be used for this decoding. Each of these techniques may match the notation in Eq. 4.

The continuation of the decoding procedure may depend on the number of successful polar decoding operations in Eq. 4. If |C_{S}|<k_{S}, the decoding is terminated in failure, otherwise the decoding continues. For every i∉C_{S} and j∈ [symbol] ^{S}, the value of u_{i,j} may be set to an erasure symbol. Then, the following Nᵣ·mₛ binary q-tuples ^{b}U_{m,i}^{S}, m∈m_{S}, i∈[Nᵣ], as defined in Eq. 3, may be considered. It is noted that for i∉C_{S}, the binary q-tuple is an all-erasure vector. Each of the binary q-tuple is replaced with the corresponding GF(q) representative symbol U_{m,i}^{S}, m∈[m_{S}] and i∈[Nᵣ] where all-erasure tuple is replaced with an appropriate erasure symbol. Then, mₛ algebraic decoding operations are carried for the mₛ Nᵣ-vectors Uₘ^{S} (as defined in Eq. 2), m∈[m_{S}]. Since MDS codes (e.g., Reed-Solomon (RS)) are considered, all-erasure symbols are successfully evaluated since |C_{S}|≦k_{S}. These newly fixed erasures are then applied to set the appropriate binary values in u_{i,j}. For example, for each corrected erasure U_{m,i}^{s}, m∈[m_{S}] and i∉C_{S}, binary information bits may be set in the corresponding binary q-tuple ^{b}U_{m,i}^{S}.

Next, the polar decoding operations may be repeated for the rows i∉C_{S} with some modification to the definition of the information index sets. By proper changing of the information index set the additional information gained from the algebraic decoding from the previous decoding stage is incorporated to the polar decoding operations. For example, the following Nᵣ−|C_{S}| polar decoding operations may be carried:

D(yᵢ,uᵢ, [symbol] ^{S-1}),i∉C_{S} (Eq. 5)

For the decoding operation of Eq. 5, the values u_{i,j}, i∉C_{S}, j∈ [symbol] ^{S} are considered as fixed and predetermined values. While these values are in fact information bits decoded based on the algebraic erasure correction operation from the previous stage, they may still be considered as fixed and predetermined. The index rows for successful polar decoding in the operation of Eq. 5 are denoted by C_{S-1}. As long as |C_{S-1}∪C_{S}|≧k_{S-1}, the binary information bits in u_{i,j,} i∉C_{S-1}∪C_{S}, j∈ [symbol] _{S-1} may be decoded based on algebraic erasure correction as carried for j∈ [symbol] _{S} in the previous stage.

The polar codewords, corresponding to rows indices in [Nᵣ] that are decoded correctly at the s-stage may be denote by Cₛ, s∈[S]. Therefore, the union of all correctly decoded codewords from stage S through stage s, inclusive, may be represented as C̅ₛ and may be calculated as:

$${\overline{C}}_{s} = {⋃}_{s \leq {s}^{′} \leq S} {C}^{{s}^{′}}$$

The decoding procedure may iterate from s′=S to s′=1. Assuming that all stages up to stage s have already been concluded (e.g. s′>s), then after stage s+1 is concluded, the information bits uᵤ have already been set for and (based in the algebraic erasure correction) also for i∈[Nᵣ] and j∈ [symbol] ^{S}\ [symbol] ^{s}. Accordingly, the following Nᵣ−|C̅ₛ₊₁| polar decoding operations may be carried at the s-stage:

D(yᵢ,uᵢ, [symbol] ^{S}),i∈[Nᵣ]\C̅ₛ₊₁ (Eq. 6)

Moreover, in addition to the predetermined all-zero bits in u_{i,j}, i∈[Nᵣ]\C̅ₛ₊₁, j∉ [symbol] ^{S}, all of the already decoded information bits u_{i,j}, i∈[Nᵣ]\C̅ₛ₊₁, j∉ [symbol] ^{S}\ [symbol] ^{s} may be considered as if they were predetermined and fixed bits. These bits may then be evaluated using the algebraic erasure decoding operations of previous decoding stages. If |C̅ₛ|<kₛ then the decoding may terminate in failure, otherwise, algebraic correction may be continued so as to set the information bits in u_{i,j}, i∈[Nᵣ]\C̅ₛ, j∈ [symbol] ^{s}. In considering the Nᵣ·mₛ q-tuples, ^{b}U_{m,i}^{s}, i∈[Nᵣ], m∈[mₛ], the binary values for ^{b}U_{m,i}^{s}, i∈C̅_{S}, m∈[mₛ] have already been successfully decoded. The remaining binary values may then be set as erasures. The corresponding symbols U_{m,i}^{s} over GF(q) may then be set where all-erasure vectors are mapped to an erasure symbol that is outside the field. Since |C̅ₛ|≧kₛ, there may be at least kₛ non-erasure symbols in each vector Uₘ^{s} and based on the MDS property of the algebraic construction, all the erasures U_{m,i}^{s}, m∈[mₛ], i∉C̅ₛ are corrected successfully. The corresponding binary information bits ^{b}U_{m,i}^{S}, m∈[mₛ], i∉C̅_{S} are set accordingly and the decoding may continue to stage s−1.

After S decoding stages are concluded for 1≦s≦S, there is a last step where Nᵣ−|C̅₁| rows may be decoded using the following polar decoding rules:

D(yᵢ,uᵢ, [symbol] ⁰),i∈[Nᵣ]\C̅₁ (Eq. 7)

For the decoding rules of Eq. 7, the predetermined ad fixed bits are all the all-zero bits u_{i,j}, i∈[Nᵣ] and j∉ [symbol] ^{S} in addition to the already decoded information bits in u_{i,j}, i∈[Nᵣ] and j∈ [symbol] ^{S}\ [symbol] ⁰. For example, the only information indices for the decoding rules of Eq. 7 are the indices in [symbol] ⁰. The decoding procedure concludes successfully only if all Nᵣ−|C̅₁| polar decoding rules of Eq. 7 have been successfully completed.

For some decoding stages, it may be the case that the polar decoding rules of Eq. 6 are skipped. For example, at a given stage interval [s,s′], 0<s<s′, it may follow that |C_{s′}|≧kₛ. In this case, all of the polar decoding operations for stages s′−1 up to s, inclusive, may be skipped, and only the algebraic decoding operations to complete the evaluation of all the information bits in u_{i,j}, i∈[Nᵣ] and j∈∪_{s≦s′} [symbol] ^{s′} need be performed.

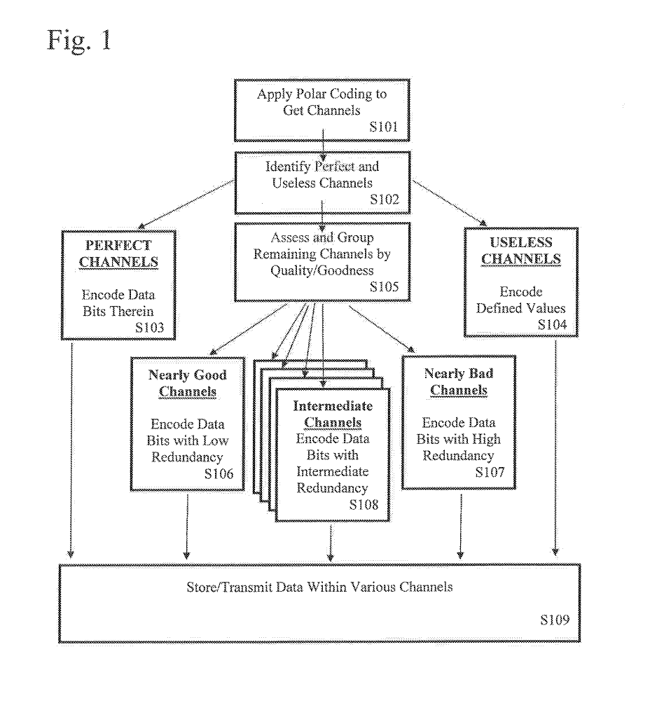

FIG. 1 is a flow chart illustrating an approach for performing progressive polar channel coding according to exemplary embodiments of the present invention. First, polar coding may be applied to the data to be stored/transmitted to create a plurality of channels (Step S101). Thereafter, some channels may be identified as perfect channels, other channels may be identified as useless channels, and still other channels may be identified as neither perfect nor useless (Step S102). The perfect channels may be used to encode information bits (Step S103), which may then be stored or transmitted (Step S109). The useless channels may be used to encode the predetermined values, which may be zero, as discussed above, however, any value may be used as long as the value is known (Step S104). The predetermined values encoded to the useless channels may then be stored/transmitted (Step S109).

Exemplary embodiments of the present invention may further assess the quality of each of the channels that are neither perfect nor useless to determine an extent to which data may be encoded therein and to determine a type of subsequent coding that would be required to encode the data without error (Step S105). The channels may be clustered into various groups that may be nearly good, nearly bad, or some level therebetween. For example, some channels may be nearly good and information bits may be encoded therein using a relatively light weight coding technique such as encoding the data bits with some low degree of redundancy (Step S106). Other channels may be nearly bad and information bits may be encoded therein using a relatively heavy weight coding technique such as encoding the data bits with some high degree of redundancy (Step S107). Other channels may be similarly grouped according to their relative quality/goodness into various intermediate channels, within which data is encoded using secondary encoding techniques with various degrees of overhead and error correction capabilities (Step S108).

Regardless of how the data bits are encoded, all of the encoded data bits, as well as the encoded predetermined bits, are either stored into flash memory (e.g. a solid state drive (“SSD”)) or transmitted (Step S109).

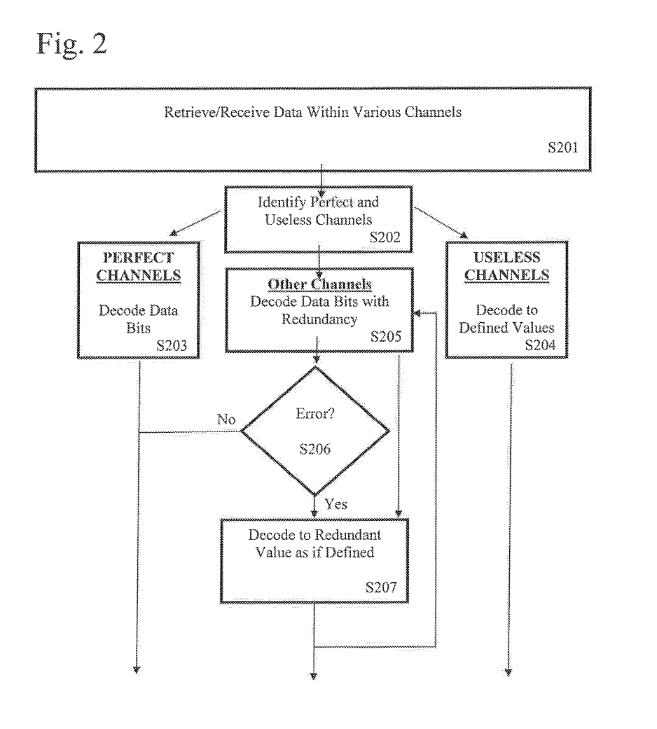

FIG. 2 is a flow chart illustrating an approach for performing progressive polar channel decoding according to exemplary embodiments of the present invention. First the data may either be retrieved from the flash memory or received from the transmission (Step S201). The retrieved/received channels may then be identified as either perfect, useless or as a particular intermediate level (Step S202). Perfect channels may be decoded into data bits using the primary polar codeword (Step S203) and the useless channels may be decoded similarly (Step S204). It is noted that as the channels are useless, their decoding would not produce useful data, however, as their values are predefined, decoding of these channels would include using the predefined values.

In decoding the other channels, multiple levels of decoding stages may be performed to retrieve the information bits (Step S205). For example, where redundancy is used, it is understood that some of the channels will not be decoded without error (Error, Yes Step S206). While a decoding failure would tend to jeopardize the polar decoding process in the conventional use, according to exemplary embodiments of the present invention, the correct bit values obtained from the successfully decoded bits of the same quality channels, but different polar codewords, may be used in place of the erroneous values. Then, these bits may be used as if the values were known and predetermined, so that the polar decoding may continue without issue (Step S207). The decoded information bits may then be used, for example, by a host device.

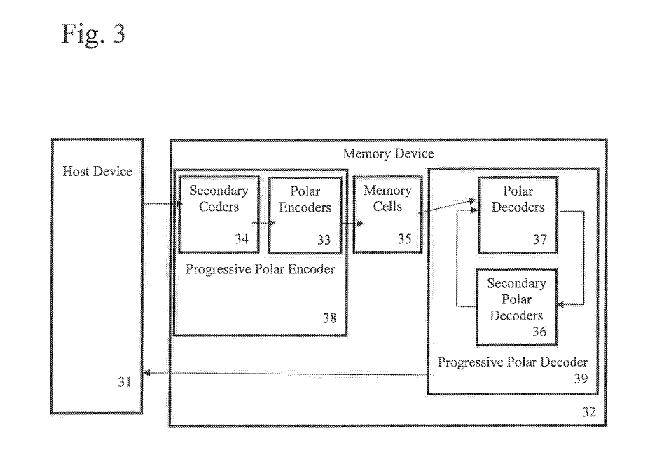

FIG. 3 is a schematic diagram illustrating a system for performing progressive polar channel coding in flash memory, or other solid state storage, in accordance with exemplary embodiments of the present invention.

A host device 31 may be in communication with a memory device 32. The memory device 32 may be a flash memory. The host device may be a computer system such as a desktop PC, a laptop/notebook PC, a tablet computer, a smartphone, a digital camera, or another type of mobile or stationary electronic device. The host device 31 may be in communication with the memory device 32, for example, along a data bus, and may be connected to the memory device 32, for example, over a universal serial bus (USB) connection, a SATA connection, a PCI connection, a wireless connection, etc.

The memory device 32 may include polar encoders 33 for mapping bit vectors to generate a set of polar codewords, and one or more secondary coders 34 for applying additional coding techniques to those channels resulting from the polar coding that are neither perfect nor useless. The combination of polar encoders and secondary encoders may provide a progressive polar encoder 38. The coded information is stored in a plurality of memory cells 35 such as multi-level cell (MLC) flash memory cells, or three level cells (TLC), for storing the encoded information bits using one of various technologies, e.g. NAND flash, VNAND flash, etc. The memory device 32 may additionally include secondary decoders 36 for decoding the one or more secondary codes from the data that has been retrieved from the memory cells 35, and polar decoders 37 for decoding the polar coding from the data that has been retrieved from the memory cells 35. The secondary decoders 36 and polar decoders 37 may operate in a progressive manner, for example, stage-by-stage, to provide a progressive polar decoder 39. Bits that are in error during a certain stage for the polar decoders 37, are corrected by the help of the secondary decoder 36. The secondary decoder 36 can correct this kind of bits since several polarcodewords are decoded in a parallel progressive manner. For example, in some cases, the error bit belonging to a polarized channel that is not perfect, but is rather an intermediate channel, may have corresponding bits that are decoded correctly by the polar decoders. Then, corrected bits are provided to the polar decoders 37, which relates to the erroneous bits as if they are predetermined and fixed bits in later decoder stages. The polar encoder 33, the secondary coder 34, the secondary decoder 36, and the polar decoder 37 may each be embodied as distinct digital signal processors, or, for example, as part of a single memory controller device.

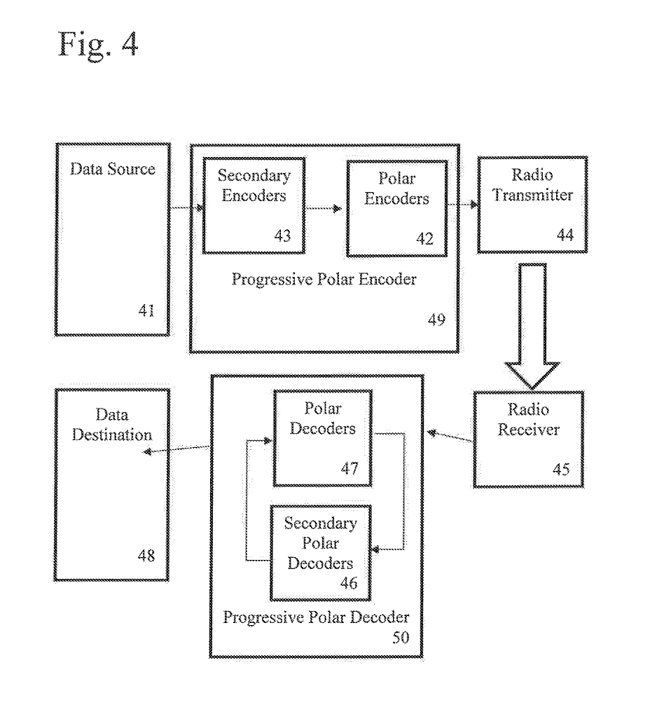

FIG. 4 is a schematic diagram illustrating a system for performing progressive polar channel coding for transmission in accordance with exemplary embodiments of the present invention. Information bits may be sent by a data source 41, such as a host device, to a polar encoder 42. The polar encoders 42 for applying polar codewords to perform polar coding. One or more secondary coders 43 may be configured for applying additional coding techniques to those channels resulting from the polar coding that are neither perfect nor useless. A radio transmitter 44 may transmit the encoded information bits. The combination of the polar encoders 42 and secondary encoders 43 provides the progressive polar encoder 49 and the combination of polar decoders 47 and secondary decoders 46, operating in a progressive stage-by-stage decoding, provide the progressive polar decoder 50.

A radio receiver 45 may receive the transmission of the encoded information bits and a secondary decoder 46 may decode the secondary encoding. Polar decoders may decode the original polar coding and may send the decoded information bits to a data destination 48, which may also be a host device.

Exemplary embodiments described herein are illustrative, and many variations can be introduced without departing from the spirit of the disclosure or from the scope of the appended claims. For example, elements and/or features of different exemplary embodiments may be combined with each other and/or substituted for each other within the scope of this disclosure and appended claims.

What is claimed is:

1. A method for storing data to be stored in a solid state device, comprising:
applying polar coding to generate a plurality of channels including a plurality of perfect channels, a plurality of useless channels, and a plurality of channels that are neither perfect nor useless;
encoding a first section of the data to be stored using the perfect channels;
encoding a predetermined value using the useless channels;
dividing the plurality of channels that are neither perfect nor useless into a plurality of groups depending upon a quality of each channel of the plurality of channels that are neither perfect nor useless;
encoding a second section of the data to be stored using the channels that are neither perfect nor useless using a coding technique that is different from the applied polar coding; and
writing the encoded data to be stored into the solid state device.

2. The method of claim 1, wherein in encoding the second section of the data to be stored using the channels that are neither perfect nor useless using a coding technique that is different from the applied polar coding, a different coding technique is used for each of the plurality of groups, and the different coding technique is selected in accordance with the channel quality of the corresponding group.

3. The method of claim 2, wherein the different coding techniques include encoding using redundancy and greater redundancy is used for groups with lesser channel quality.

4. The method of claim 1, further including:
reading the encoded data from the flash memory;
decoding the read data from the perfect channels using polar decoding; and
decoding the read data from the plurality of channels that are neither perfect nor useless using the polar decoding and a second decoding technique that is different from the polar decoding.

5. The method of claim 4, wherein in decoding the read data from the plurality of channels that are neither perfect nor useless using the polar decoding, erroneous decoding is cured by using, as a predetermined value, redundant data that was successfully decoded from the read data from the plurality of channels that are neither perfect nor useless.

6. The method of claim 4, wherein the decoded read data is transmitted to a host device.

7. The method of claim 1, wherein the data to be stored is received from a host device.

8. A method for transmitting data to be transmitted, comprising:
applying polar coding to generate a plurality of channels including a plurality of perfect channels, a plurality of useless channels, and a plurality of channels that are neither perfect nor useless;
encoding a first section of the data to be transmitted on the perfect channels;
encoding a predetermined value on the useless channels;
dividing the plurality of channels that are neither perfect nor useless into a plurality of groups depending upon a quality of each channel of the plurality of channels that are neither perfect nor useless;
encoding a second section of the data to be transmitted on the channels that are neither perfect nor useless using a coding technique that is different from the applied polar coding; and
sending the encoded data to a recipient.

9. The method of claim 8, wherein the encoded data is sent to the recipient wirelessly.

10. The method of claim 8, wherein in encoding the second section of the data to be transmitted using the channels that are neither perfect nor useless using a coding technique that is different from the applied polar coding, a different coding technique is used for each of the plurality of groups, and the different coding technique is selected in accordance with the channel quality of the corresponding group.

11. The method of claim 10, wherein the different coding techniques include encoding using redundancy and greater redundancy is used for groups with lesser channel quality.

12. The method of claim 8, further including:
receiving the encoded data at the recipient;
decoding the received data from the perfect channels using polar decoding; and
decoding the received data from the plurality of channels that are neither perfect nor useless using the polar decoding and a second decoding technique that is different from the polar decoding.

13. The method of claim 12, wherein in decoding the received data from the plurality of channels that are neither perfect nor useless using the polar decoding, erroneous decoding is cured by using, as a predetermined value, redundant data that was successfully decoded from the received data from the plurality of channels that are neither perfect nor useless.

14. The method of claim 12, wherein the decoded received data is transmitted to a host device.

15. The method of claim 8, wherein the data to be transmitted is received from a host device.

16. A method for encoding data, comprising:
applying polar coding to generate a plurality of channels including a plurality of perfect channels, a plurality of useless channels, and a plurality of channels that are neither perfect nor useless;
encoding a first section of the data to be stored using the perfect channels;
encoding a predetermined value using the useless channels;
dividing the plurality of channels that are neither perfect nor useless into a plurality of groups including at least a first group of channels having a relatively high channel quality and a second group of channels having a relatively low channel quality;
encoding a second section of the data to be stored using the channels of the first group of channels having the relatively high channel quality using a first level of redundancy; and
encoding a third section of the data to be stored using the channels of the second group of channels having the relatively low channel quality using a second level of redundancy that is greater than the first level of redundancy.

17. The method of claim 16, further including writing the encoded data to be stored into a solid state device.

18. The method of claim 16, further including transmitting the encoded data to a recipient.

19. The method of claim 18, wherein the encoded data is transmitted to the recipient wirelessly.

20. The method of claim 18, wherein the encoded data is decoded using polar decoding, and, in decoding the channels that are neither perfect nor useless, erroneous decoding is cured by using, as a predetermined value, redundant data that was successfully decoded.
